(19) United States
(12) Patent Application Publication
(10) Pub. No.: US 2011/0052810 A1
(43) Pub. Date: Mar. 3, 2011

(54) FILM FORMING METHOD AND STORAGE MEDIUM

(75) Inventors: Yumiko Kawano, Yamanashi (JP); Susumu Arima, Yamanashi (JP); Akinobu Kakimoto, Yamanashi (JP); Toshiyuki Hirota, Tokyo (JP); Takakazu Kiyomura, Tokyo (JP)

(73) Assignees: Tokyo Electron Limited, Tokyo (JP); Elpida Memory, Inc., Tokyo (JP)

(21) Appl. No.: 12/918,152

(22) PCT Filed: Feb. 18, 2009
(86) PCT No.: PCT/JP2009/052727

§ 371 Date: Nov. 12, 2010

(30) Foreign Application Priority Data
Feb. 19, 2008 (JP) 2008-037563

(51) Int. Cl. C23C 16/22

(52) U.S. Cl. 427/255.395

(57) ABSTRACT

An AxByOz-type oxide film can be produced by introducing a first organic metal compound source material, a second organic metal compound source material and an oxidizer into a processing chamber and forming the AxByOz-type oxide film on a substrate. In the production, a compound which has a low vapor pressure and has an organic ligand capable of being decomposed with an oxidizer to produce CO is used as the first organic metal compound source material, a metal alkoxide is used as the second organic metal compound source material, and gaseous O₃ or O₂ is used as the oxidizer. It is absolutely necessary to introduce the second organic metal compound source material immediately before the introduction of the oxidizer.

### FIELD OF THE INVENTION

The present invention relates to a film forming method for forming an AxByOz-type oxide film such as an Sr—Ti—O-based film or the like and a storage medium which stores a program for executing the same.

### BACKGROUND OF THE INVENTION

Along with the trend toward high integration of integrated circuits in semiconductor devices, DRAMs is required to have a smaller area of memory cells and a larger memory capacity. To this end, metal-insulator-metal (MIM) capacitors have attracted attention. MIM-structured capacitors employ a high-k dielectric material such as strontium titanate (SrTiO₃) as a material of an insulating film (dielectric film).

As for a method for forming an AxByOz-type high-k dielectric oxide film such as an SrTiO₃ film or the like, there has been conventionally widely used an atomic layer deposition (ALD) method for forming a film on a substrate such as a semiconductor wafer or the like by using an organic metal compound source material containing a metal and an oxidizer (see, e.g., “Plasma enhanced atomic layer deposition of SrTiO₃ thin films with Sr(tmhd)₂ and Ti(i-OPr)₄”, J. H. Lee et al., J. Vac. Scl. Technol. A20(5), September/October 2002).

However, when a cyclopentadienyl compound, e.g., Sr(C₅(CH₃)₅)₂, having a low vapor pressure and an organic ligand which is easily decomposed with an oxidizer to produce CO is used as an organic metal compound, the usage of O₂ or O₃ as the oxidizer causes excessive decomposition of the organic ligand, wherein the CO produced by the excessive decomposition is bonded to a metal. Accordingly, a metal carbonate having a low vapor pressure is generated and remains in a high-k dielectric oxide film to thereby increase concentration of C as impurities in the film. When the concentration of C increases, it is difficult to crystallize the high-k dielectric oxide film during annealing.

On the other hand, in case of using H₂O as the oxidizer, the above-described problems do not occur. Since, however, H₂O tends to remain more easily in the chamber compared to O₂ or O₃, a long period of time is required for a purge step thereof to thereby remarkably decrease throughput of film formation.

Meanwhile, when an Sr—Ti—O-based film is formed simply by alternately forming an SrO layer and a TiO layer, a desired composition is not obtained after the film formation due to adsorption inhibition or the like. Therefore, the present inventors have suggested a technique including sequences of repeating an SrO film formation step continuously or a TiO film formation step continuously (Japanese Patent Application No. 2007-228745).

However, when a cyclopentadienyl compound, e.g., Sr(C₅(CH₃)₅)₂, used as an organic metal compound, due to its low vapor pressure, repetitive ALD sequences of forming an SrO layer using, e.g., Sr(C₅(CH₃)₅)₂, cause a residual Sr organic compound to remain in a central portion of the semiconductor wafer. As a result, concentration of C in the film increases.

### SUMMARY OF THE INVENTION

It is therefore an object of the present invention to provide a film forming method capable of forming an AxByOz-type oxide film while achieving high throughput without increasing the C concentration in a film even in case of using an organic compound source material having a low vapor pressure and an organic ligand which is easily decomposed with an oxidizer to produce CO.

It is another object of the present invention to provide a storage medium which stores a program for executing a method for achieving the above-described purpose.

In accordance with a first aspect of the present invention, there is provided a film forming method for forming an AxByOz-type oxide film on a substrate, including loading the substrate in a processing chamber; and introducing a first gaseous organic metal compound source material containing a first metal, a second gaseous organic metal compound source material containing a second metal, and an oxidizer into the processing chamber. Herein, a compound having an organic ligand which is decomposed with an oxidizer to produce CO is used as the first organic metal compound source material, a metallic alkoxide is used as the second organic metal compound source material, and gaseous or O₂ is used as the oxidizer. Further, the second organic metal compound source material is introduced immediately before the introduction of the oxidizer.

In the film forming method, the AxByOz-type oxide film may be formed on the substrate by performing a plurality of cycles, each cycle sequentially including a process for introducing the first organic metal compound source material into the processing chamber, a process for purging the processing chamber, a process for introducing the second organic metal compound source material into the processing chamber, a process for purging the processing chamber, a process for introducing the oxidizer into the processing chamber and a process for purging the processing chamber.

Further, in the film forming method, the AxByOz-type oxide film may be formed on the substrate by performing a plurality of cycles, each cycle including a step for introducing the first organic metal compound source material into the processing chamber and then purging the processing chamber once or a predetermined number of times and a step for introducing the second organic metal compound source material into the processing chamber, purging the processing chamber, introducing the oxidizer into the processing chamber and then purging the processing chamber once or a predetermined number of times.

As the first organic metal compound source material, a cyclopentadienyl compound or an amide-based compound may be used. Preferably, the first organic metal compound source material is an Sr compound, the second organic metal compound is a Ti compound, and the AxByOz-type oxide film is an Sr—Ti—O-based film.

In accordance with a second aspect of the present invention, there is provided a film forming method for forming an AxByOz-type oxide film on a substrate by loading the substrate into a processing chamber and introducing a first gaseous organic metal compound source material containing a first metal, a second gaseous organic metal compound source material containing a second metal, and an oxidizer into the processing chamber, the film forming method including: a first film formation step including a process for introducing, as the first organic metal compound, a compound having an organic ligand which is decomposed with the oxidizer to produce CO into the processing chamber, a process for introducing the oxidizer into the processing chamber, and then a process for purging the processing chamber; and a second film formation step including a process for introducing the second organic metal compound source material into the processing chamber, a process for introducing the oxidizer into the processing chamber and then a process for purging the processing chamber. In the film forming method, each of the first and the second film formation step is continuously repeated multiple times, and the first film formation step is repeated less than six times.

In the film forming method in accordance with the second aspect, a cyclopentadienyl compound or an amide-based compound may used as the first organic metal compound source material. Further, metallic alkoxide may used as the second organic metal compound source material. Furthermore, the oxidizer may be gaseous O₃ or O₂. Preferably, the first organic metal compound source material is an Sr compound, the second organic metal compound source material is a Ti compound, and the AxByOz-type oxide film is an Sr—Ti—O-based film.

In accordance with a third aspect of the present invention, there is provided a storage medium for storing a program which runs on a computer and, when executed, controls a film forming apparatus to perform a method for forming an AxByOz-type oxide film on a substrate, the method including: loading the substrate into a processing chamber; and introducing a first gaseous organic metal compound source material containing a first metal, a second gaseous organic metal compound source material containing a second metal, and an oxidizer into the processing chamber. A compound having an organic ligand which is decomposed with an oxidizer to produce CO is used as the first organic metal compound source material, a metallic alkoxide is used as the second organic metal compound source material, and gaseous O₃ or O₂ is used as the oxidizer. Further, the second organic metal compound source material is introduced immediately before the introduction of the oxidizer.

In accordance with a fourth aspect of the present invention, there is provided a storage medium for storing a program which runs on a computer and, when executed, controls a film forming apparatus to perform a method for forming an AxByOz-type oxide film on a substrate, by loading the substrate into a processing chamber and introducing a first gaseous organic metal compound source material containing a first metal, a second gaseous organic metal compound source material containing a second metal, and an oxidizer into the processing chamber, the method including a first film formation step and a second film formation step.

The first film formation step includes a process for introducing, as the first organic metal compound source material, a compound having an organic ligand which is decomposed with the oxidizer to produce CO into the processing chamber, a process for introducing the oxidizer into the processing chamber and then a process for purging the processing chamber. The second film formation step includes a process for introducing the second organic metal compound source material into the processing chamber, a process for introducing the oxidizer into the processing chamber and then a process for purging the processing chamber. Further, each of the first and the second film formation step is continuously performed multiple times, and the first film formation step is repeated less than six times.

In accordance with the present invention, an AxByOz-type oxide film is formed by introducing into a processing chamber a first organic metal compound source material, a second organic metal compound source material and an oxidizer. At this time, a compound having a low vapor pressure and an organic ligand which is easily decomposed with an oxidizer to produce CO is used as the first organic metal compound source material; a metal alkoxide is used as the second organic metal compound source material; and gaseous O₃ or O₂ is used as the oxidizer.

Further, the second organic metal compound source material is introduced immediately before the introduction of the oxidizer. Therefore, O₃ or O₂ can be prevented from directly contacting with the first organic metal compound source material, thereby suppressing generation of CO caused by excessive decomposition of the organic ligand of the first organic metal compound. As a consequence, concentration of C in the film can be prevented from increasing due to generation of carbonate having a low vapor pressure which is caused by bonding between CO and a metal of the first organic metal compound.

Moreover, when a compound having a low vapor pressure and an organic ligand which is readily decomposed with an oxidizer to produce CO is used as the first organic metal compound source material, a first film formation step including a process for introducing the first organic metal compound source material into the processing chamber, a process for introducing the oxidizer into the processing chamber and a process for purging the processing chamber is repeated less than six times. Hence, it is possible to prevent the first organic metal compound from remaining in the central portion of the substrate, and, accordingly, is possible to prevent increase of C concentration in the film.

### BRIEF DESCRIPTION OF THE DRAWINGS

FIG. 1 is a cross sectional view showing a schematic configuration of a film forming apparatus which can be used to perform a film forming method of the present invention.

FIG. 2 describes an example of a film forming sequence in accordance with a first embodiment of the present invention.

FIG. 3 illustrates another example of the film forming sequence in accordance with the first embodiment of the present invention.

FIG. 4 provides an SIMS analysis result of an element concentration in an Sr—Ti—O film obtained during test examples 1-3.

FIG. 5 presents an SIMS analysis result of an element concentration in an Sr—Ti—O film obtained during test examples 1-4.

FIG. 6 represents a film forming sequence in accordance with a second embodiment of the present invention.

FIG. 7 depicts another example of a processing gas supply mechanism.

### DETAILED DESCRIPTION OF THE EMBODIMENT

Hereinafter, embodiments of the present invention will be described with reference to the accompanying drawings.

Here, there will be described a case where an Sr—Ti—O-based film such as an SrTiO₃ film is formed as an AₓB_{y}O_{z}-type oxide film.

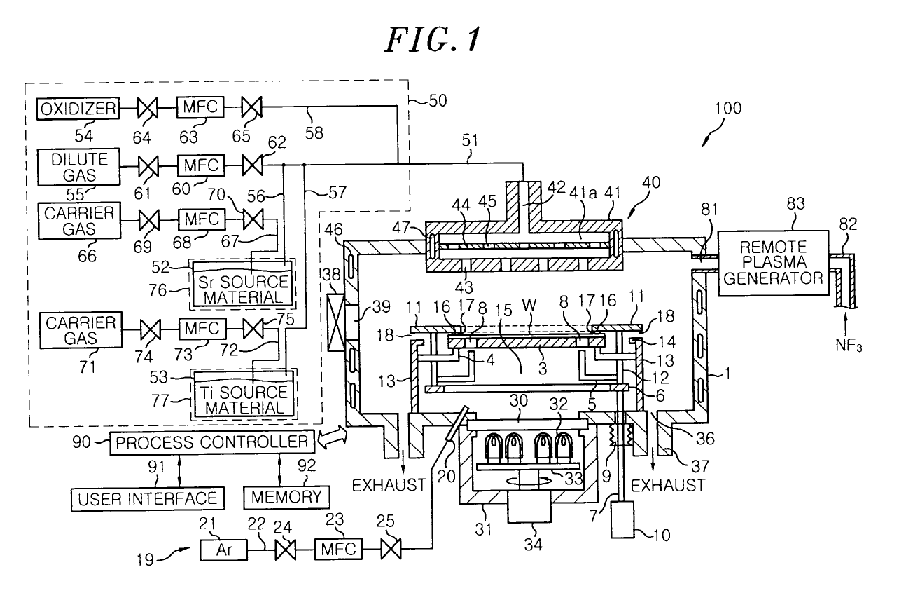

FIG. 1 is a cross sectional view showing a schematic configuration of a film forming apparatus which can be used to perform a film forming method of the present invention. A film forming apparatus 100 shown in FIG. 1 includes a cylindrical or box-shaped processing chamber 1 made of, e.g., aluminum or the like, in which there is provided a mounting table 3 for mounting thereon a semiconductor wafer W serving as a substrate to be processed. The mounting table 3 is made of, e.g., a carbon material, aluminum compound such as aluminum nitride, or the like, having a thickness of about 1 mm.

A cylindrical partition wall 13 made of, e.g., aluminum, stands on a bottom portion of the processing chamber 1 at an outer peripheral side of the mounting table 3. A bent portion 14 is formed by horizontally bending an upper portion of the partition wall 13 in an L shape. By installing the cylindrical partition wall 13, an inert gas purge area 15 is formed at a backside of the mounting table 3. A top surface of the bent portion 14 is positioned substantially on a same plane with a top surface of the mounting table 3 and is spaced from the outer periphery of the mounting table 3 with connection rods 12 inserted therebetween. The mounting table 3 is supported by three supporting arms 4 (only two being shown) extending from an upper inner wall of the partition wall 13.

A plurality of, e.g., three, lifter pins 5 (only two being shown) are provided under the mounting table 3 so as to protrude upward from a ring-shaped support member 6 in an L shape. The support member 6 is provided to be raised and lowered by an elevation rod 7 which passes through the bottom portion of the processing chamber 1, and the elevation rod 7 is raised and lowered by an actuator 10 positioned below the processing chamber 1.

The mounting table 3 has insertion through holes 8 at portions corresponding to the lifter pins 5, so that the lifter pins 5 can pass through the insertion through holes 8. Thus, the lifter pins 5 can be raised by the actuator 10 through the elevation rod 7 and support member 6, and lift up the semiconductor wafer W. The portion of the processing chamber 1 into which the elevation rod 7 is inserted is covered with a bellows 9 to prevent air from entering the processing chamber 1 through this portion.

A clamp ring member 11 made of ceramic, e.g., aluminum nitride, and having a substantially annular shape conforming to a contour shape of the circular semiconductor wafer W is arranged above a peripheral portion of the mounting table 3 so as to hold and fix the peripheral portion of the semiconductor wafer W onto the mounting table 3. The clamp ring member 11 is connected to the support member 6 via the connection rods 12, and thus can be moved up and down together with the lifter pins 5. The lifter pins 5, the connection rods 12 or the like are made of ceramic such as alumina or the like.

A plurality of contact protrusions 16 are formed below a lower surface of an inner peripheral side of the clamp ring member 11 while being spaced from each other at a substantially regular interval in a circumferential direction. When the semiconductor wafer W is clamped, bottom surfaces of the contact protrusions 16 come into contact with the top surface of the peripheral portion of the semiconductor wafer W and press the wafer W.

Further, each of the contact protrusions 16 has a diameter of about 1 mm and a height of about 50 μm, so that a first gas purge gap 17 having an annular shape is formed at this portion when the semiconductor wafer W is clamped. Here, an overlapping amount L1 (a passage length of the first gas purge gap 17) of the peripheral portion of the semiconductor wafer W and the inner periphery of the clamp ring 11 during clamping is several millimeters (mm).

A peripheral portion of the clamp ring member 11 is arranged above the bent portion 14 formed at the upper end of the partition wall 13, and a second gas purge gap 18 having an annular shape is formed therebetween. The width (height) of the second gas purge gap 18 is about 500 μm, which is about ten times larger than the width of the first gas purge gap 17. An overlapping amount of the peripheral portion of the clamp ring member 11 and the bent portion 14 (a passage length of the second gas purge gap 18) is, e.g., about 10 mm. Accordingly, inert gases in the inert gas purge area 15 can be discharged through both gaps 17 and 18 into a processing space.

An inert gas supply mechanism 19 for supplying an inert gas to the inert gas purge area 15 is provided at the bottom portion of the processing chamber 1. The inert gas supply mechanism 19 includes: a gas nozzle 20 for introducing an inert gas, e.g., Ar gas, into the inert gas purge area 15; an Ar gas supply source 21 for supplying an Ar gas as the inert gas; and a gas line 22 for supplying an Ar gas from the Ar gas supply source 21 to the gas nozzle 20. Further, the gas line 22 is provided with a mass flow controller (MFC) 23 serving as a flow rate controller, and opening/closing valves 24 and 25. Instead of Ar gas, other rare gas such as He gas or the like may be used as the inert gas.

A transmission window 30 made of a heat ray transmission material such as quartz or the like is airtightly provided at a place right under the mounting table 3 at the bottom portion of the processing chamber 1, under which a box-shaped heating chamber 31 is arranged to surround the transmission window 30. The heating chamber 31 has therein a plurality of heating lamps 32 serving as a heating unit, which are installed on a rotatable table 33 serving as a reflective mirror as well. The rotatable table is rotated by a rotating motor 34 provided at a bottom portion of the heating chamber 31 through a rotation axis. Accordingly, heat rays emitted from the heating lamps 32 are irradiated to the backside of the mounting table 3 through the transmission window 30, thereby heating the mounting table 3.

Furthermore, a gas exhaust port 36 is provided at a peripheral portion of the bottom portion of the processing chamber 1. The gas exhaust port 36 is connected to a gas exhaust line 37 connected to a vacuum pump (not shown). By exhausting gases through the gas exhaust port 36 and the gas exhaust line 37, a pressure in the processing chamber 1 can be maintained at a certain vacuum level. Formed at a sidewall of the processing chamber 1 are a loading/unloading port 39 for loading and unloading a semiconductor wafer W and a gate valve 38 for opening and closing the loading/unloading port 39.

Meanwhile, a shower head 40 for supplying a source gas or the like into the processing chamber 1 is provided at a ceiling portion of the processing chamber 1 to face the mounting table 3. The shower head 40 includes a disc-shaped head main body 41 which is made of, e.g., aluminum, and has a space 41a therein. A gas inlet port 42 is provided at a ceiling portion of the head main body 41. The gas inlet port 42 is connected, through a line 51, to a processing gas supply mechanism 50 for supplying processing gases required to form an Sr—Ti—O-based film. A plurality of gas injection holes 43 for discharging the gas supplied into the head main body 41 to the processing space provided in the processing chamber 1 is formed over the entire surface of the bottom portion of the head main body 41, so that the gas is discharged onto the entire surface of the semiconductor wafer W.

Further, a diffusion plate 44 having a plurality of gas distribution holes 45 is disposed in the space 41a of the head main body 41, so that the gas can be more uniformly supplied to the surface of the semiconductor wafer W. Moreover, cartridge heaters 46 and 47 for temperature control are built in the sidewall of the processing chamber 1, the sidewall of the shower head 40 and the wafer facing surface of the shower head 40 where the gas injection holes are provided, so that the sidewall of the processing chamber 1 and portions of the shower head which contact with the gas can be maintained at a predetermined temperature.

The processing gas supply mechanism 50 includes an Sr source material reservoir 52 for storing an Sr source material, a Ti source material reservoir 53 for storing a Ti source material, an oxidizer supply source 54 for supplying an oxidizer, and a dilute gas supply source 55 for supplying a dilute gas, e.g., Ar gas, for diluting the gas in the processing chamber 1.

The line 51 connected to the shower head 40 is connected to a line 56 extending from the Sr source material reservoir 52, a line 57 extending from the Ti source material reservoir 53 and a line 58 extending from the oxidizer supply source 54. The line 51 is also connected to the dilute gas supply source 55. The line 51 is provided with a mass flow controller (MFC) 60 serving as a flow rate controller, and valves 61 and 62 disposed at an upstream and a downstream side thereof. Further, the line 58 is provided with a mass flow controller (MFC) 63 serving as a flow rate controller and valves 64 and 65 located at an upstream and a downstream side thereof.

The Sr source material reservoir 52 is connected via the line 67 to a carrier gas supply source 66 for supplying a carrier gas for bubbling, e.g., Ar gas or the like. The line 67 is provided with a mass flow controller (MFC) 68 serving as a flow rate controller, and valves 69 and 70 located at an upstream and a downstream side thereof. Moreover, the Ti source material reservoir 53 is connected via the line 72 to a carrier gas supply source 71 for supplying a carrier gas such as Ar gas or the like. The line 72 is provided with a mass flow controller (MFC) 73 serving as a flow rate controller, and valves 74 and 75 located at an upstream and a downstream side thereof.

The Sr source material reservoir 52 and the Ti source material reservoir 53 are provided with heaters 76 and 77, respectively. Besides, the Sr source material stored in the Sr source material reservoir 52 and the Ti source material stored in the Ti source material reservoir 53 are supplied to the processing chamber 1 through bubbling while being heated by the heaters 76 and 77. Although it is not shown, a line for supplying the Sr source material or the Ti source material in a vaporized state is also provided with a heater.

Formed at an upper sidewall of the processing chamber 1 is a cleaning gas inlet port 81 for introducing NF₃ gas as a cleaning gas. The cleaning gas inlet port 81 is connected to a line 82 for supplying NF₃ gas. The line 82 is provided with a remote plasma generator 83. Thus, NF₃ gas supplied through the line 82 is turned into a plasma in the remote plasma generator 83 and supplied into the process chamber 1, thereby cleaning the processing chamber 1. Moreover, the remote plasma generator 83 may be provided at a place located right above the shower head 40 so that a cleaning gas can be supplied through the shower head 40. Besides, F₂ may be used instead of NF₃, and plasma-less thermal clean using ClF₃ or the like may be performed without using a remote plasma.

The film forming apparatus 100 includes a process controller 90 including a micro processor (computer), and components of the film forming apparatus 100 are connected to and controlled by the process controller 90. Further, the process controller 90 is connected to a user interface including a keyboard through which an operator inputs commands for controlling respective components of the film forming apparatus 100 and/or a display for visually displaying operation statuses of respective components of the film forming apparatus 100.

Moreover, the process controller 90 is connected to a storage unit 92 for storing therein control programs to be used in realizing various processes performed by the film forming apparatus 100 under the control of the process controller 90, programs, i.e., recipes to be used in performing predetermined processes by the respective components of the film forming apparatus 100 under processing conditions, various databases and/or the like. The recipes are stored in a storage medium of the storage unit 92. The storage medium may be a fixed device such as a hard disk or the like, or a portable device such as a CD-ROM, a DVD, a flash memory or the like. Besides, the recipes may be properly transmitted from other devices via, e.g., a dedicated line.

If necessary, any one of the recipes is read out from the storage unit 92 in accordance with an instruction inputted from the user interface 91 and executed by the process controller 90. Accordingly, a desired process is performed in the film forming apparatus 100 under the control of the process controller 90.

The following is description of embodiments of a film formation processing method performed by the film forming apparatus configured as described above.

### First Embodiment

The first embodiment solves a problem of residual C generated when a compound having an organic ligand which is decomposed with an oxidizer to produce CO is used as an Sr source material and gaseous O₃ or O₂ is used as an oxidizer. C can be easily left over to remain in a formed film when the Sr source material is a compound having a low vapor pressure and an organic ligand which is decomposed with the oxidizer to produce CO, such as a cyclopentadienyl compound, e.g., Sr(C₅(CH₃)₅)₂:Bis(pentamethylcyclopentadienyl)strontium or Sr(DPM)₂:Bis(dipivaloymethanato)strontium, or an amide-based compound such as Sr(NH₂)₂:Diamido-strontium. Hence, it is very advantageous to solve the problem of the residual C by this embodiment.

To this end, in this embodiment, alkoxide, e.g., Ti(OiPr)4:Titanium(IV)iso-propoxide, is used as a Ti source material. Moreover, when a film is formed by introducing the Sr source material, the Ti source material and the oxidizer into the processing chamber 1, the Ti source material is always introduced immediately before the introduction of the oxidizer.

Hereinafter, specific description thereof will be provided.

At first, the gate valve 38 is opened, and a semiconductor wafer W is loaded into the processing chamber 1 through the loading/unloading port 39 and mounted on the mounting table 3. The semiconductor wafer W is heated by the mounting table 3 that has been heated by heat rays emitted from the heating lamps 32 and transmitted through the transmission window 30. Then, while a dilute gas, e.g., Ar gas, is supplied at a flow rate ranging from about 100 to 800 mL/sec (sccm) from a dilute gas supply source 55, the processing chamber 1 is vacuum-exhausted by a vacuum pump (not shown) through the gas exhaust port 36 and gas exhaust line 37 so that a pressure in the processing chamber 1 is maintained within a range from about 39 to 665 Pa. At this time, the semiconductor wafer W is heated to be maintained a temperature within a range from, e.g., 200 to 400° C.

Next, a flow rate of a dilute gas, e.g., Ar gas, is set to be maintained within a range from about 100 to 500 mL/min (sccm), and a pressure in the processing chamber 1 is controlled to be kept within a range from about 6 to 266 Pa, to start actual film formation. The pressure in the processing chamber 1 is controlled by an automatic pressure controller (APC) provided in the gas exhaust line 37 (not shown).

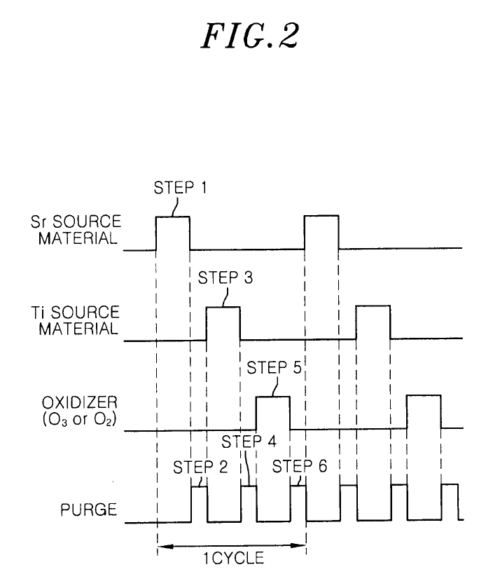

As shown in FIG. 2, an example of the actual film forming sequence of this embodiment includes, as one cycle, a process for supplying an Sr source material into the processing chamber 1 (step 1); a process for purging the processing chamber 1 (step 2); a process for supplying a Ti source material into the processing chamber 1 (step 3); a process for purging the processing chamber 1 (step 4); a process for supplying an oxidizer into the processing chamber 1 (step 5); and a process for purging the processing chamber 1 (step 6). This cycle is repeated multiple times.

Since the Ti source material is always introduced immediately before the introduction of the oxidizer, i.e., the oxidizer is not introduced right after the introduction of the Sr source material, the Sr source material is covered by the Ti source material and then is oxidized by the oxidizer. Accordingly, O₃ or O₂ is prevented from directly contacting with the Sr source material, and this can suppress generation of CO which is caused by excessive decomposition of the organic ligand of the Sr source material.

More specifically, when the oxidizer is introduced after the supply of the Ti source material, H₂O is generated by reaction of the oxidizer and alkoxide used as the Ti source material and, at the same time, alkoxide groups are removed as alcohol by hydrolysis reaction in the presence of H₂O. Therefore, it is possible to prevent the alkoxide groups of the Ti source material from being decomposed apart by O₃ or O₂ and causing C to remain in the film.

Moreover, the generated H₂O has a function of breaking the bonding between Sr and the ligand of the Sr source material. Therefore, it is possible to prevent the ligand of the Sr source material from being decomposed apart by O₃ or O₂ to produce CO. Hence, generation of carbonate having a low vapor pressure, such as SrCO₃ or SrC₂O₄.H₂O (hydrate), which is caused by bonding between Sr and CO can be suppressed, and this can prevent C from remaining in the film. As a result, the concentration of C in the film can be reduced.

Especially when a cyclopentadienyl compound, e.g., Sr(C₅(CH₃)₅)₂, is used as the Sr source material, cyclopentadienyl groups can be easily separated from a metal by H₂O, which is preferable.

Hereinafter, specific film forming conditions will be described.

In the step 1, an Sr source material is supplied through bubbling from the Sr source material reservoir 52 heated to a temperature within a range from about 150 to 230° C. by the heater 76 into the processing chamber 1 through the shower head 40. As described above, a compound having a low vapor pressure and an organic ligand which is decomposed with an oxidizer and produces CO is used as the Sr source material. The Sr source material may be a conventionally used material such as Sr(DPM)₂, Sr(C₅(CH₃)₅)₂ or the like.

Especially, Sr(C₅(CH₃)₅)₂ that has a comparatively high vapor pressure and is easily handled is preferably used among materials having a low vapor pressure. When the Sr source material is supplied, a dilute gas, e.g., Ar gas, is supplied at a flow rate ranging from about 100 to 500 mL/min (sccm) from the dilute gas supply source 55, and a carrier gas, e.g., Ar gas, is supplied at a flow rate ranging from about 50 to 500 mL/min (sccm) from the carrier gas supply source 66. Moreover, the supply of the Sr source material (step 1) is performed for about 0.1 to 20 seconds.

In the step 3, a Ti source material is supplied through bubbling from the Ti source material reservoir 53 heated by the heater 77 into the processing chamber 1 through the shower head 40. As described above, alkoxide is used as the Ti source material. For example, Ti(OiPr)₄ or the like can be preferably used. In that case, the Ti source material reservoir 53 containing Ti(OiPr)₄ is heated to a temperature ranging from about 40 to 70° C.

When the Ti source material is supplied, a dilute gas, e.g., Ar gas, is supplied at a flow rate ranging from about 100 to 500 mL/min (sccm) from the dilute gas supply source 55, and a carrier gas, e.g., Ar gas, is supplied at a flow rate ranging from about 100 to 500 mL/min (sccm) from the carrier gas supply source 71. The supply of the Ti source material (step 3) is carried out for, e.g., about 0.1 to 20 seconds.

In the step 5 of supplying the oxidizer, the oxidizer is supplied from the oxidizer supply source 54 into the processing chamber 1 through the shower head 40. Accordingly, the Ti source material adsorbed onto the surface of the semiconductor wafer W is decomposed and oxidized. The Sr source material is also decomposed and oxidized by H₂O generated when the Ti source material is oxidized. As a consequence, an Sr—Ti—O-based oxide film is formed.

The supply of the oxidizer (step 5) is carried out for, e.g., about 0.1 to 20 seconds, in a state where a dilute gas, e.g., Ar gas, is supplied at a flow rate ranging from about 100 to 500 mL/min (sccm) from the dilute gas supply source 55. As described above, O₃ gas or O₂ gas is used as the oxidizer. O₂ gas may be supplied in a state of plasma. When O₃ gas is used as the oxidizer, it is supplied at a flow rate ranging from about 50 to 200 g/m³N by using an ozonizer as the oxidizer supply source 54. In that case, O₂ gas supplied at a flow rate ranging from about 100 to 1000 mL/min (sccm) may be used along with O₃ gas.

In the purge processes of the steps 2, 4 and 6, the preceding supply of the Sr source material gas, the Ti source material gas and the oxidizing gas is stopped, and a dilute gas, e.g., Ar gas, is supplied at a flow rate ranging from about 200 to 1000 mL/min (sccm) from the dilute gas supply source 55 into the processing chamber 1. Besides, the purge process may be performed by fully opening a pressure control mechanism of the processing chamber 1 without supplying gases. This process is performed for, e.g., about 0.1 to 20 seconds.

The steps 1 to 6 are preferably repeated more than 20 times, so that an Sr—Ti—O-based film (SrTiO₃ film) having a desired film thickness is formed.

Upon completion of the film formation, a dilute gas is supplied at a predetermined flow rate from the dilute gas supply source 55 and the supply of all gases is stopped. Then, the processing chamber is vacuum-exhausted, and the semiconductor wafer W is unloaded from the processing chamber 1 by a transfer arm.

The process controller 90 controls the valves or the mass flow controllers in accordance with the above-described sequence based on the recipes stored in the storage unit 92.

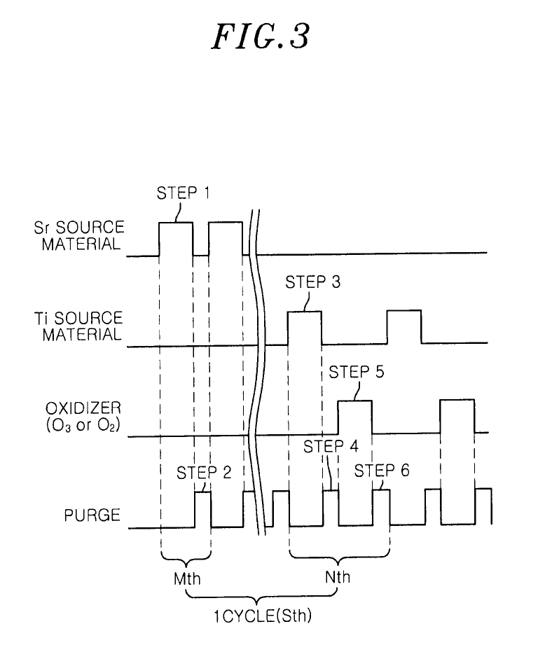

As illustrated in FIG. 3, in another example of the film forming sequence of this embodiment, for one cycle, a process for supplying an Sr source material into the processing chamber 1 (step 1) and a process for purging the processing chamber 1 (step 2) are repeated m times and, then, a process for supplying a Ti source material into the processing chamber 1 (step 3), a process for purging the processing chamber 1 (step 4), a process for supplying an oxidizer into the processing chamber 1 (step 5) and a process for purging the processing chamber 1 (step 6) are repeated n times. This cycle is repeated s times (m, n and being positive integers).

Further, there may be employed another method for repeating, as one cycle, the steps 1 and 2 ml times, the steps 3 to 6 n1 times, the steps 1 and 2 m2 times, and the steps 3 to 6 n2 times. In this method, the cycle is repeated t times (m1, m2, n1, n2 and t being positive integers). Preferably, m, m1 and m2 are integers ranging from 1 to 5; n, n1 and n2 are integers ranging from 1 to 4; and s and t are integers ranging from 1 to 200 which allow a desired film thickness to be obtained.

Hereinafter, test examples of actual film formation performed by the embodiment of the present invention will be described.

### Test Example 1-1

In the apparatus of FIG. 1, after a temperature of a mounting table was heated to about 300° C. by controlling a lamp power so that a temperature of a 200 mm Si wafer can be heated to about 290° C. at a pressure for film forming, the Si wafer was loaded into the processing chamber 1 by the arm of a transfer robot and an Sr—Ti—O-based film was formed. Herein, Sr (C₅ (CH₃)₅)₂ was used as Sr source material, contained in the Sr source material reservoir 52 heated to about 160° C., and supplied into the processing chamber through bubbling method while using Ar gas as a carrier gas.

Further, Ti(OiPr)₄ was used as Ti source material, contained in the Ti source material reservoir 53 heated to about 45° C., and supplied into the processing chamber through bubbling method while using Ar gas as a carrier gas. Furthermore, O₃ gas having concentration of about 180 g/m³N was used as an oxidizer. The O₃ gas was obtained by passing O₂ gas at a flow rate of about 500 mL/min (sccm) and N₂ gas at a flow rate of about 0.5 mL/min (sccm) through an ozonizer.

When the Si wafer was mounted on the mounting table by the arm, a pressure in the processing chamber was controlled to be maintained at about 133 Pa (1 Torr) while dilute Ar gas was supplied at a flow rate of about 300 mL/min (sccm). During that, the temperature of the Si wafer was increased to a film formation temperature, i.e., about 290° C. Then, the pressure in the processing chamber was controlled to be maintained at about 40 Pa (0.3 Torr) for about 10 seconds while supplying the dilute Ar gas at a flow rate of about 300 mL/min (sccm), and film formation was performed by repeating the steps 1 to 6 of the sequence shown in FIG. 2.

Specifically, in the step 1, the Sr source material supply process was executed for about 10 seconds by supplying a carrier Ar gas at a flow rate of about 50 mL/min (sccm) and dilute Ar gas at a flow rate of about 200 mL/min (sccm) and exhausting the processing chamber 1 by fully opening the pressure control mechanism of the processing chamber 1. In the step 2, the purge process was carried out for about 10 seconds by fully opening the pressure control mechanism of the processing chamber 1 without supplying gases.

In the step 3, the Ti source material supply process was performed for about 10 seconds by supplying a carrier Ar gas at a flow rate of about 100 mL/min (sccm) and dilute Ar gas at a flow rate of about 200 mL/min (sccm) and exhausting the processing chamber 1 by fully opening the pressure control mechanism of the processing chamber 1. In the step 4, the purge process was carried out for about 10 seconds by fully opening the pressure control mechanism of the processing chamber 1 without supplying gases, as in the step 2.

In the step 5, the oxidizing process was carried out for about 5 seconds by supplying O₃ gas as an oxidizer and exhausting the processing chamber 1 while fully opening the pressure control mechanism of the processing chamber 1. Finally, in the step 6, the purge process was performed for about 10 seconds by fully opening the pressure control mechanism without supplying gas.

After repeating the steps 1 to 6 41 times, the dilute Ar gas was supplied at a flow rate of about 300 mL/min (sccm) for about 30 seconds while exhausting the processing chamber 1 by fully opening the pressure control mechanism of the processing chamber 1. Thereafter, the Si wafer was unloaded from the processing chamber 1.

A thickness of the Sr—Ti—O film (SrTiO₃ film) formed by the above-described sequence was measured to be about 5 nm. Further, a film composition ratio, i.e., an Sr/Ti atomic ratio, measured by an XRF (X-ray fluorescence spectrometer) was about 0.7. Moreover, concentration of C in the film which was measured by SIMS (secondary ion mass spectrometry) was about 5×10²⁰ atoms/cm². Namely, the concentration of C in the film was reduced compared to that in a comparative example to be described later (corresponding to a second embodiment) in which an oxidizer would directly contact with an Sr source material.

### Test Example 1-2

Here, the apparatus shown in FIG. 1 was also used, and an Sr source material, a Ti source material and an oxidizer same as those of the test example 1-1 were supplied under the same conditions as those of the test example 1-1 except for a film forming sequence.

To be specific, as in the test example 1-1, after a Si wafer was mounted on the mounting table by the transfer arm, dilute Ar gas was supplied at a flow rate of about 300 mL/min (sccm) and the temperature of the Si wafer was increased to a film formation temperature, i.e., about 290° C., while maintaining a pressure in the processing chamber at about 133 Pa (1 Torr).

Next, the pressure in the processing chamber 1 was controlled to be maintained at about 40 Pa (0.3 Torr) for about 10 seconds while supplying dilute Ar gas at a flow rate of about 300 mL/min (sccm). In that state, as one cycle, the steps 1 and 2 were repeated twice under the same conditions as those of the test example 1-1, the steps 3 to twice under the same conditions as those of the test example 1-1, the steps 1 and 2 twice under the same conditions as those of the test example 1-1 and, then, the steps 3 to 6 were performed once under the same conditions as those of the test example 1-1. This cycle was repeated 17 times.

Then, the processing chamber 1 was exhausted by fully opening the pressure control mechanism of the processing chamber 1 and supplying the dilute Ar gas at a flow rate of about 300 mL/min (sccm) for about 30 seconds. Thereafter, the Si wafer was unloaded from the processing chamber 1.

A thickness of the Sr—Ti—O film (SrTiO₃ film) formed by the above sequences was measured to be about 7 nm. Further, a film composition ratio, i.e., an Sr/Ti atomic ratio, measured by an XRF (X-ray fluorescence spectrometer) was about 1.2. Moreover, concentration of C in the film which was measured by SIMS (secondary ion mass spectrometry) was about 8×10²⁰ atoms/cm³. Namely, the concentration of C in the film was reduced compared to that in a comparative example to be described later (corresponding to a second embodiment) in which an oxidizer would directly contact with an Sr source material.

### Test Example 1-3

Here, the apparatus shown in FIG. 1 was also used, and an Sr source material, a Ti source material and an oxidizer same as those of the test example 1-1 were supplied under the same conditions as those of the test example 1-1 except for a film forming sequence, a temperature of an Sr source material reservoir and a temperature of a Ti source material reservoir.

To be specific, the temperature of the Sr source material reservoir was set to about 150° C., and the temperature of the Ti source material reservoir was set to about 54° C. Further, as in the test example 1-1, after a Si wafer was mounted on the mounting table by the arm, dilute Ar gas was supplied at a flow rate of about 300 mL/min (sccm), and the temperature of the Si wafer was increased to a film formation temperature, i.e., about 290° C., while maintaining a pressure in the processing chamber 1 at about 133 Pa (1 Torr).

Next, the pressure in the processing chamber 1 was controlled to be kept at about 40 Pa (0.3 Torr) for about 10 seconds while supplying dilute Ar gas at a flow rate of about 300 mL/min (sccm). In that state, as one cycle, the steps 1 and 2 were repeated three times under the same conditions as those of the test example 1-1 and, then, the steps 3 to 6 were performed once under the same conditions as those of the test example 1-1. After repeating this cycle 30 times, the processing chamber 1 was exhausted by fully opening the pressure control mechanism of the processing chamber 1 and supplying the dilute Ar gas at a flow rate of about 300 mL/min (sccm) for about 30 seconds. Thereafter, the Si wafer was unloaded from the processing chamber.

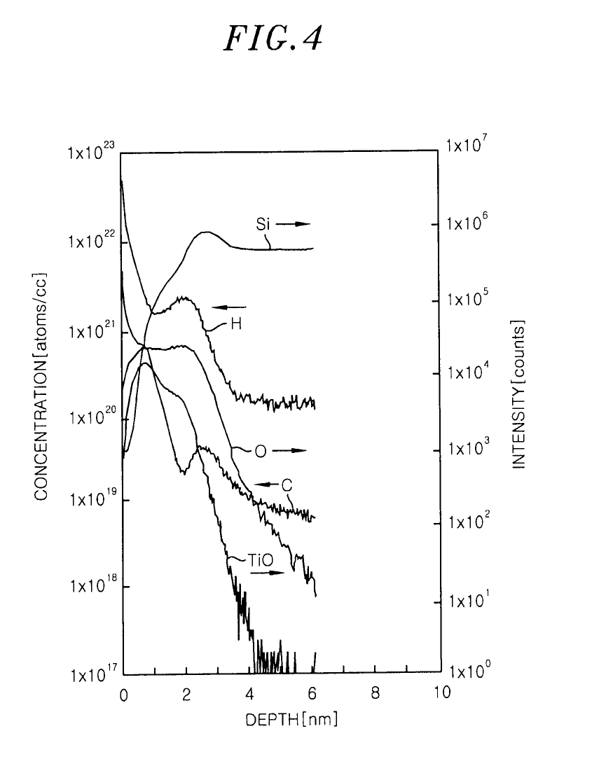

A thickness of the Sr—Ti—O film (SrTiO₃ film) formed by the above sequence was measured to be about 3.9 nm. Further, a film composition ratio, i.e., an Sr/Ti atomic ratio, measured by an XRF (X-ray fluorescence spectrometer) was about 2.4 at the center and about 2.2 at the edge portion of the wafer. Moreover, concentrations of elements in the film which were measured by SIMS (secondary ion mass spectrometry) are shown in FIG. 4. As can be seen from FIG. 4, the concentration of C in the film was about 6.0×10²⁰ atoms/cm², resulting in a reduction compared to that in a comparative example to be described later (corresponding to a second embodiment) in which an oxidizer would directly contact with an Sr source material.

### Test Example 1-4

Similarly, the apparatus shown in FIG. 1 was used. Here, an Sr source material, a Ti source material and an oxidizer same as those of the test example 1-1 were supplied under the same conditions as those of the test example 1-1 except for a film forming sequence.

Specifically, as in the test example 1-1, after a Si wafer was mounted on the mounting table by the arm, dilute Ar gas was supplied at a flow rate of about 300 mL/min (sccm), and the temperature of the Si wafer was increased to a film formation temperature, i.e., about 290° C., while maintaining a pressure in the processing chamber 1 at about 133 Pa (1 Torr).

Next, the pressure in the processing chamber 1 was controlled to be maintained at about 40 Pa (0.3 Torr) for about 10 seconds while supplying dilute Ar gas at a flow rate of about 300 mL/min (sccm). In that state, as one cycle, the steps 1 and 2 were repeated five times under the same conditions as those of the test example 1-1 and, then, the steps 3 to 6 were repeated twice under the same conditions as those of the test example 1-1. After repeating this cycle 20 times, the processing chamber 1 was exhausted by fully opening the pressure control mechanism of the processing chamber 1 and supplying the dilute Ar gas at a flow rate of about 300 mL/min (sccm) for about 30 seconds. Then, the Si wafer was unloaded from the processing chamber.

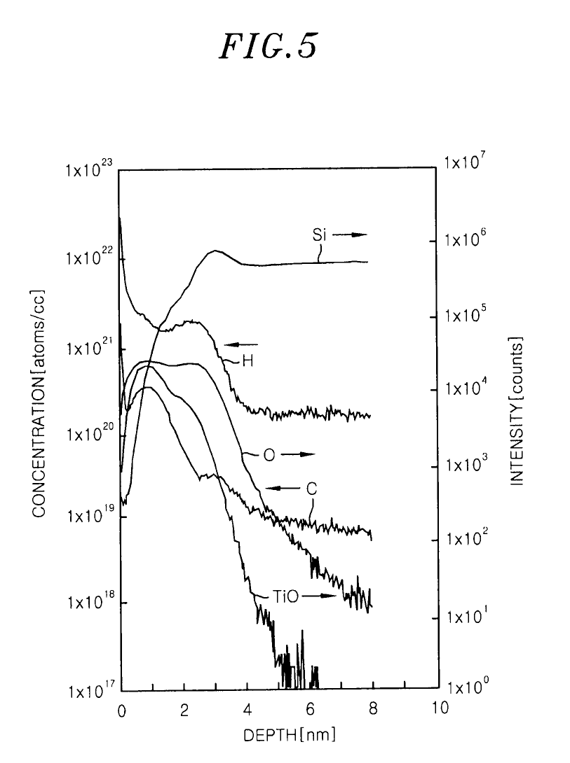

A thickness of the Sr—Ti—O film (SrTiO₃ film) formed by the above sequences was measured to be about 4.0 nm. Further, a film composition ratio, i.e., an Sr/Ti atomic ratio, measured by an XRF (X-ray fluorescence spectrometer) was about 0.8 at the center and about 0.7 at the edge portion. Moreover, concentrations of elements in the film which were measured by SIMS (secondary ion mass spectrometry) are shown in FIG. 5. As can be seen from FIG. 5, the concentration of C in the film was about 3.2×10²⁰ atoms/cm³. This demonstrates a reduction achieved in comparison to that in a comparative example to be described later (corresponding to a second embodiment) in which an oxidizer would directly contact with an Sr source material.

### Comparative Example

Here, the apparatus shown in FIG. 1 was used, and an Sr source material, a Ti source material and an oxidizer same as those of the test example 1-1 were supplied under the same conditions as those of the test example 1-1 except for a film forming sequence.

To be specific, as in the test example 1-1, after a Si wafer was mounted on the mounting table by the arm, dilute Ar gas was supplied at a flow rate of about 300 mL/min (sccm), and the temperature of the Si wafer was increased to a film formation temperature, i.e., about 290° C., while maintaining a pressure in the processing chamber 1 at about 133 Pa (1 Torr). Then, the pressure in the processing chamber 1 was controlled to be maintained at about 40 Pa (0.3 Torr) for about 10 seconds while supplying dilute Ar gas at a flow rate of about 300 mL/min (sccm).

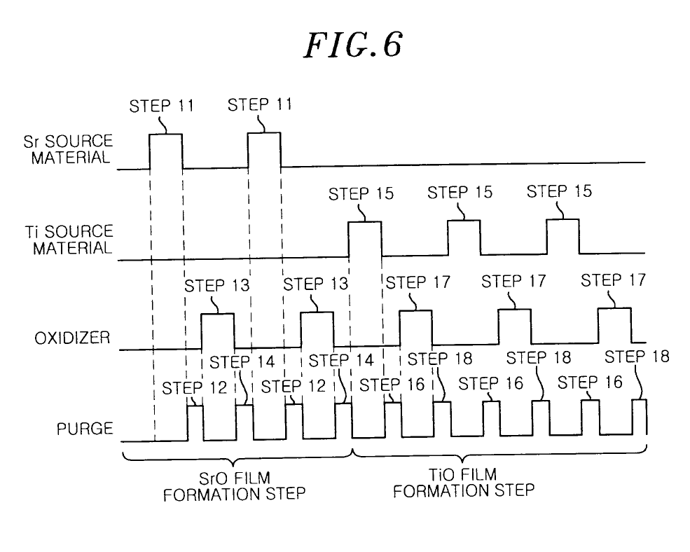

In that state, the sequence of the second embodiment as shown in FIG. 6 was performed. More specifically, as one cycle, the SrO film forming process of the steps 11 to 14 was repeated twice and, then, the TiO film forming process of the steps 15 to 18 was repeated three times. After repeating this cycle 34 times, the processing chamber 1 was exhausted by fully opening the pressure control mechanism of the processing chamber 1 and supplying dilute Ar gas at a flow rate of about 300 mL/min (sccm) for about 30 seconds. Thereafter, the Si wafer was unloaded from the processing chamber.

Herein, the step 11 was performed under the same conditions as those of the step 1 of the test example 1-1; the oxidizing process of the steps 13 and 17 was executed under the same conditions as those of the step 5 of the test example 1-1; the step 15 was carried out under the same conditions as those of the step 3 of the test example 1-1; and the purge process of the steps 12, 14, 16 and 18 was performed under the same conditions as those of the step 2.

A thickness of the Sr—Ti—O film (SrTiO₃ film) formed by the above sequence was measured to be about 18.7 nm. Further, a film composition ratio, i.e., an Sr/Ti atomic ratio, measured by an XRF (X-ray fluorescence spectrometer) was about 1.2 at the center and about 0.8 at the edge portion. Moreover, concentration of C in the film which was measured by SIMS (secondary ion mass spectrometry) was about 3.0×10²¹ atoms/cm³. The concentration of C in the film was increased compared to those in the test examples 1-1 to 1-4 in which an oxidizer did not directly contact with an Sr source material.

### Second Embodiment

The second embodiment prevents an organic metal compound of the Sr source material from remaining in a central portion of a wafer by using, as an Sr source material, a compound having an organic ligand which is decomposed with an oxidizer to produce CO, especially, a compound having a low vapor pressure and an organic ligand which is easily decomposed with an oxidizer to produce CO, e.g., a cyclopentadienyl compound, such as Sr(C₅(CH₃)₅)₂ (Bis(pentamethylcyclopentadienyl)strontium) and Sr(DPM)₂ (Bis(dipivaloylmethanato) strontium) or an amide-based compound such as Sr(NH₂)₂.

As mentioned earlier, the conventional ALD method is disadvantageous in that combination of source materials may cause adsorption inhibition and this hinders achievement of a desired film composition after the film formation. However, as described in Japanese Patent Application No. 2007-228745, by repeating the SrO film formation step continuously or the TiO film formation step continuously multiple times, adsorption inhibition can be avoided and a film composition close to a desired film composition can be obtained. Besides, it is possible to form an Sr—Ti—O-based film having a desired composition ranging from an Sr-rich composition to a Ti-rich composition.

However, when a compound having a low vapor pressure such as a cyclopentadienyl compound, e.g., Sr(C₅(CH₃)₅)₂, is used as the Sr source material, an excessive Sr source material remains in the central portion of the wafer after repeating the SrO film formation step multiple times. This increases concentration of C in the central portion of the wafer and, as a result, leads to an increase in an Sr/Ti ratio and a film thickness.

Therefore, in this embodiment, an Sr—Ti—O-based film such as SrTiO₃ or the like is formed by repeating the SrO film formation step for forming a thin SrO film and the TiO film formation step for forming a thin TiO film, as illustrated in FIG. 6. The SrO film formation step includes a process for supplying an Sr source material into the processing chamber 1 (step 11), a process for purging the processing chamber 1 (step 12), a process for decomposing and oxidizing the Sr source material by supplying an oxidizer into the processing chamber 1 (step 13) and a process for purging the processing chamber 1. The TiO film formation step includes a process for supplying a Ti source material into the processing chamber 1 (step 15), a process for purging the processing chamber 1 (step 16), a process for decomposing and oxidizing the Ti source material by supplying the oxidizer into the processing chamber 1 (step 17) and a process for purging the processing chamber 1 (step 18).

In this embodiment, the SrO film formation step is not repeated more than five times, preferably more than three times. Namely, the SrO film formation step is continued less than six times, preferably less than four times. Although the TiO film has a composition of TiOx (X being 1 to 2) due to an actual variation in concentration of oxygen in the TiO film formation step, it is called as a “TiO film” for convenience.

In the second embodiment as well as in the first embodiment, at first, the gate valve 38 is opened, and a semiconductor wafer W is loaded into the processing chamber 1 through the loading/unloading port 39 and mounted on the mounting table 3. The semiconductor wafer W is heated to a predetermined temperature ranging from, e.g., about 200 to 400° C., by the mounting table 3 that has been heated by the heating lamps 32.

Then, a dilute gas, e.g., Ar gas, is supplied at a flow rate ranging from about 100 to 800 mL/sec (sccm) from the dilute gas supply source 55, and the processing chamber 1 is vacuum-exhausted by a vacuum pump (not shown) through the gas exhaust port 36 and the gas exhaust line 37 so that a pressure in the processing chamber 1 ranges from about 6 to 665 Pa. Next, the pressure in the processing chamber 1 is controlled to be kept at a film formation pressure, i.e., ranging from about 13 to 266 Pa, while supplying a dilute gas, e.g., Ar gas, at a flow rate ranging from about 100 to 500 mL/sec (sccm). Thereafter, actual film formation is carried out.

In the Ti source material supply process of the step 15, the Ti source material is not particularly limited. Preferably, it is possible to use alkoxide such as Ti(OiPr)₄ (Titanium(IV iso-propoxide), Ti(OiPr)₂(DPM)₂ (Di-iso-propoxy Bis(dipivaloylmethanato)Titanium) or the like. The Ti source material reservoir 53 containing Ti(OiPr)₄ is heated to a temperature ranging from about 40 to 70° C., and the Ti source material reservoir 53 containing Ti(OiPr)₂(DPM)₂ is heated to a temperature ranging from about 150 to 230° C.

As in the first embodiment, the process controller 90 controls the valves or the mass flow controllers in accordance with the above-described sequence based on the recipes stored in the storage unit 92.

Hereinafter, test examples of actual film formation performed by this embodiment of the present invention will be described.

### Test Example 2-1

In the apparatus of FIG. 1, a temperature of a mounting table was set to about 320° C. by controlling a lamp power, and a 200-mm Si wafer was loaded into the processing chamber 1 by the arm of the transfer robot. Then, an Sr—Ti—O-based film was formed. Sr(C₅(CH₃)₅)₂ contained in the reservoir heated to about 160° C. was supplied as an Sr source material into the processing chamber 1 through bubbling method while using Ar gas as a carrier gas. Ti(OiPr)₄ contained in the reservoir heated to about 45° C. was supplied as a Ti source material into the processing chamber 1 through bubbling method while using Ar gas as a carrier gas.

Further, O₃ gas having concentration of about 180 g/m³N was used as an oxidizer. The O₃ gas was obtained by passing O₂ gas at a flow rate of about 500 mL/min (sccm) and N₂ gas at a flow rate of about 0.5 mL/min (sccm) through an ozonizer.

After the Si wafer was mounted on the mounting table by the arm, dilute Ar gas was supplied at a flow rate of about 300 mL/min (sccm), and the temperature of the Si wafer was increased to a film formation temperature, i.e., about 290° C., while maintaining a pressure in the processing chamber at about 133 Pa (1 Torr). Then, the pressure in the processing chamber was controlled to be maintained at about 40 Pa (0.3 Torr) for about 10 seconds while supplying the dilute Ar gas at a flow rate of about 300 mL/min (sccm). The film formation was performed by repeating the steps 11 to 18 as described above.

The Sr source material supply process of the step 11 was executed for about 10 seconds by supplying carrier Ar gas at a flow rate of about 50 mL/min (sccm) and dilute Ar gas at a flow rate of about 200 mL/min (sccm) while exhausting the processing chamber 1 by fully opening the pressure control mechanism of the processing chamber 1. The purge process of the step 12 was carried out for about 10 seconds by fully opening the pressure control mechanism without supplying gas.

The Sr source material oxidizing process of the step 13 was performed for about 10 seconds by using O₃ gas as an oxidizer while exhausting the processing chamber 1 by fully opening the pressure control mechanism of the processing chamber 1. The purge process of the step 14 was carried out for about 10 seconds by fully opening the pressure control mechanism without supplying gasses.

The Ti source material supply process of the step 15 was performed for about 10 seconds by supplying carrier Ar gas at a flow rate of about 200 mL/min (sccm) and dilute Ar gas at a flow rate of about 100 mL/min (sccm) while exhausting the processing chamber 1 by fully opening the pressure control mechanism of the processing chamber 1. The purge process of the step 16 was carried out for about 10 seconds by fully opening the pressure control mechanism without supplying gasses.

The Ti source material oxidizing process of the step 17 and the purge process of the step 18 were performed under the same conditions as those of the steps 13 and 14, respectively.

Next, the SrO film formation step of the steps 11 to 14 was repeated twice and, then, the TiO film formation step of the steps 15 to 18 was repeated twice. Thereafter, the steps 11 to 14 were repeated twice and, then, the steps 15 to 18 were performed once. After repeating this cycle 24 times, the processing chamber 1 was exhausted by fully opening the pressure control mechanism of the processing chamber 1 while supplying the dilute Ar gas at a flow rate of about 300 mL/min (sccm) for about 30 seconds. Thereafter, the Si wafer was unloaded from the processing chamber 1. A film thickness of the Sr—Ti—O film (SrTiO₃ film) formed on a lower electrode Ru by the above-described sequence was measured to be about 10 nm. Further, concentration of C in the film which was measured by SIMS (secondary ion mass spectrometry) was about 2×10²¹ atoms/cm³. Moreover, a film composition ratio, i.e., an Sr/Ti atomic ratio, measured by an XRF (X-ray fluorescence spectrometer) was about 1.4 at the center and about 1.1 at the edge portion. Besides, uniformity of the film thickness was about 4.3% at 1 σ.

### Comparative Example 2-1

An Sr—Ti—O film (SrTiO₃ film) was formed on a lower electrode Ru under the same conditions as those of the test example 2-1 except for a film forming sequence. Here, one cycle consists of repeating an SrO film formation step of the steps 11 to 14 eight times and a TiO film formation step of the steps 15 to 18 ten times. This cycle was repeated eight times.

As a result, a thickness of a formed film was about 15 nm; concentration of C in the film was about 7×10²¹ atoms/cm³; an Sr/Ti atomic ratio was about 1.6 at the center and about 0.8 at the edge portion of the wafer; and film thickness uniformity was about 22% at 1 σ. Namely, the C concentration, the film thickness uniformity and the composition uniformity were remarkably lowered compared to those in the test example 2-1.

### Comparative Example 2-2

An Sr—Ti—O film (SrTiO₃ film) was formed on a lower electrode Ru under the same conditions as those of the test example 2-1 except for a film forming sequence. Here, one cycle consists of repeating an SrO film formation step of the steps 11 to 14 six times and a TiO film formation step of the steps 15 to 18 twice. This cycle was repeated 14 times. As a result, a thickness of a formed film was about nm, and concentration of C in the film was 1.5 times greater than that in an Sr—Ti—O film formed by repeating the SrO film formation step twice and under.

The present invention can be variously modified without being limited to the above-described embodiments.

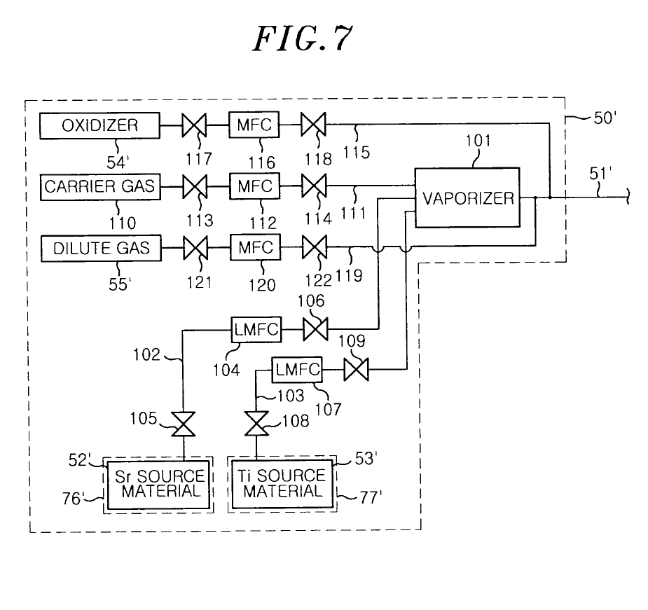

For example, although the processing gas supply mechanism 50 for supplying a source material through bubbling method is used in the above-described film forming apparatus, it is also possible to use a processing gas supply mechanism 50′ for supplying a source material by using a vaporizer as shown in FIG. 7.

The processing gas supply mechanism 50′ includes an Sr source material reservoir 52′ for storing an Sr source material dissolved in a solvent; a Ti source material reservoir 53′ for storing a Ti source material dissolved in a solvent; an oxidizer supply source 54′ for supplying an oxidizer; and a vaporizer 101 for vaporizing the Sr source material and the Ti source material. A line 102 is provided from the Sr source material reservoir 52′ to the vaporizer 101, and a line 103 is provided from the Ti source material reservoir 53′ to the vaporizer 101.

A liquid is supplied from the Sr source material reservoir 52′ and the Ti source material reservoir 53′ to the vaporizer 101 by a pressure-feed gas, a pump or the like. The line 102 is provided with a liquid mass flow controller (LMFC) 104 serving as a flow rate controller, and valves 105 and 106 located at an upstream and a downstream side thereof. Further, the line 103 is provided with a liquid mass flow controller (LMFC) 107 and valves 108 and 109 located at an upstream and a downstream side thereof.

The Sr source material reservoir 52′ and the Ti source material reservoir 53′ are provided with a heater 76′ and a heater 77′, respectively. Further, the Sr source material dissolved in the solvent and stored in the Sr source material reservoir 52′ and the Ti source material dissolved in the solvent and stored in the Ti source material reservoir 53′ are heated to respective predetermined temperatures by the heaters 76′ and 77′ and supplied in a liquid state to the vaporizer 101 by a pump, a pressure-feed gas or the like. Furthermore, although it is not illustrated, lines for allowing passage of the Sr source material and the Ti source material may be provided with heaters.

The vaporizer 101 is connected via a line 51′ to the shower head 40. The vaporizer 101 is also connected to a line 111 which extends from the carrier gas supply source 110 for supplying a carrier gas, e.g., Ar gas. By supplying the carrier gas to the vaporizer 101, an Sr source material and a Ti source material that have been heated to predetermined temperatures ranging from, e.g., 100 to 200° C., and then vaporized in the vaporizer 101 are supplied into the processing chamber 1 through the line 51′ and the shower head 40. The line 111 is provided with a mass flow controller (MFC) 112 serving as a flow rate controller and valves 113 and 114 located at an upstream and a downstream side thereof.

A line 115 is provided from the oxidizer supply source 54′ to the line 51′ so that an oxidizer is supplied from the oxidizer supply source 54′ into the processing chamber 1 through the lines 115 and 51′ and the shower head 40. The line 115 is provided with a mass flow controller (MFC) 116 serving as a flow rate controller and valves 117 and 118 located at an upstream and a downstream side thereof.

Further, the gas supply mechanism 50′ includes a dilute gas supply source 55′ which supplies a dilute gas such as Ar gas or the like to dilute gases in the processing chamber 1. The dilute gas supply source 55′ is connected via a line 119 to the line 51′, so that Ar gas for dilution can be supplied into the processing chamber 1 through the lines 119 and 51′ and the shower head 40. The line 119 is also provided with a mass flow controller (MFC) 120 serving as a flow rate controller and valves 121 and 122 located at an upstream and a downstream side thereof.

When an Sr—Ti—O-based film is formed by using the gas supply mechanism 50′, a film forming process is performed in accordance with a sequence basically the same as that described above, except that it differs in the Sr source material supply process of the step 1 and the Ti source material supply process of the step 3.

In the Sr source material supply process of step 1, the Sr source material in the Sr source material reservoir 52′ is dissolved in a solvent such as octane, cyclohexane, toluene or the like. Herein, the concentration of the Sr source material is preferably in the range from about 0.05 to 1 mol/L. The Sr source material is supplied to the vaporizer 101 heated to a temperature ranging from about 100 to 300° C. and then vaporized therein. At this time, a dilute gas, e.g., Ar gas, is supplied at a flow rate ranging from about 100 to 500 mL/min (sccm) from the dilute gas supply source 55′, and a carrier gas, e.g., Ar gas, is supplied at a flow rate ranging from about 100 to 500 mL/min (sccm) from the carrier gas supply source 110. This process is performed for a substantially same period of time as in the supply through bubbling method mentioned above.

In the Ti source material supply process of the step 3, the Ti source material dissolved in a solvent such as octane, cyclohexane, toluene or the like in the Ti source material reservoir 53′ is supplied to the vaporizer 101 heated to a temperature within a range from about 100 to 200° C. and vaporized therein. The concentration thereof is preferably about 0.05 to 1 mol/L.

At this time, a dilute gas, e.g., Ar gas, is supplied at a flow rate ranging from about 100 to 500 mL/min (sccm) from the dilute gas supply source 55′, and a carrier gas, e.g., Ar gas, is supplied at a flow rate ranging from about 100 to 500 mL/min (sccm) from the carrier gas supply source 110. Alternatively, a Ti source material in a liquid state may be directly supplied to the vaporizer 101 and vaporized therein. Further, this process is performed for a substantially same period of time as in the supply through bubbling method.

In the film forming apparatus of the above embodiment, a substrate to be processed is heated by lamps. However, it may be heated by a resistance heater. Further, although a semiconductor wafer is used as a substrate to be processed in the above-described embodiments, the substrate to be processed is not limited thereto and may be another substrate such as a glass substrate for use in an FPD or the like.

Moreover, in the aforementioned embodiments, the processing chamber is exhausted by fully opening the pressure control mechanism during film formation. However, a pressure in the processing chamber may be maintained at a desired level ranging from about 13 to 266 Pa by operating the pressure control mechanism. In addition, although a purge process is performed by fully opening the pressure control mechanism without supplying gases in the aforementioned embodiments, a purge process may be performed by exhausting the processing chamber by fully opening the pressure control mechanism or by maintaining the pressure in the processing chamber at a pressure ranging from about 20 to 266 Pa, while supplying an inert gas, e.g., Ar gas, at a flow rate ranging from about 100 to 1000 mL/min (sccm).

Besides, in the above-described embodiments, an Sr—Ti—O film such as SrTiO₃ or the like is formed by using an Sr source material and a Ti source material. However, it is not limited thereto, and another AxByOz-type oxide film such as BST, PZT, SRO or the like may be formed by using an organic compound source material containing another metal.

### INDUSTRIAL APPLICABILITY

An oxide film such as an Sr—Ti—O-based film or the like formed by the method in accordance with the present invention is effectively used in an electrode for MIM-structured capacitors.

1. A film forming method for forming an AxByOz oxide film on a substrate, comprising:
loading the substrate in a processing chamber; and
introducing a first gaseous organic metal compound source material comprising a first metal, a second gaseous organic metal compound source material comprising a second metal, and an oxidizer into the processing chamber,
wherein a compound having an organic ligand which is decomposed with an oxidizer to produce CO is employed as the first organic metal compound source material; a metallic alkoxide is employed as the second organic metal compound source material; gaseous O₃ or O₂ is employed as the oxidizer; and the second organic metal compound source material is introduced immediately before the introduction of the oxidizer.

2. The film forming method of claim 1, wherein the AxByOz oxide film is formed on the substrate by performing a plurality of cycles, each cycle sequentially including a process for introducing the first organic metal compound source material into the processing chamber, a process for purging the processing chamber, a process for introducing the second organic metal compound source material into the processing chamber, a process for purging the processing chamber, a process for introducing the oxidizer into the processing chamber and a process for purging the processing chamber.

3. The film forming method of claim 1, wherein the AxByOz oxide film is formed on the substrate by performing a plurality of cycles, each cycle comprising introducing the first organic metal compound source material into the processing chamber and then purging the processing chamber once or a predetermined number of times and introducing the second organic metal compound source material into the processing chamber, purging the processing chamber, introducing the oxidizer into the processing chamber, and then purging the processing chamber once or a predetermined number of times.

4. The film forming method of claim 1, wherein the first organic metal compound source material is a cyclopentadienyl compound or an amide comprising compound.

5. The film forming method of claim 1, wherein the first organic metal compound source material is an Sr compound; the second organic metal compound is a Ti compound; and the AxByOz oxide film is an Sr—Ti—O comprising film.

6. A film forming method for forming an AxByOz oxide film on a substrate by loading the substrate into a processing chamber and introducing a first gaseous organic metal compound source material comprising a first metal, a second gaseous organic metal compound source material comprising a second metal, and an oxidizer into the processing chamber, the film forming method comprising:
(A) forming a first film by introducing, as the first organic metal compound, a compound having an organic ligand which is decomposed with the oxidizer to produce CO into the processing chamber, a then introducing the oxidizer into the processing chamber, and then purging the processing chamber; and
(B) forming a second film by introducing the second organic metal compound source material into the processing chamber, a process for introducing the oxidizer into the processing chamber and then a process for purging the processing chamber,
wherein each of the forming first (A) and the second (B) film is continuously repeated multiple times, and the forming first film (A) is repeated less than six times.

7. The film forming method of claim 6, wherein the first organic metal compound source material is a cyclopentadienyl compound or an amide comprising compound.

8. The film forming method of claim 6, wherein the second organic metal compound source material is metallic alkoxide.

9. The film forming method of claim 6, wherein the oxidizer is gaseous O₃ or O₂.

10. The film forming method of claim 6, wherein the first organic metal compound source material is an Sr compound; the second organic metal compound source material is a Ti compound; and the AxByOz oxide film is an Sr—Ti—O comprising film.

11. A non transitory computer-readable storage medium for storing instructions executable by an information processing apparatus which includes a processor, which when executed, controls a film forming apparatus to perform a method for forming an AxByOz oxide film on a substrate, the method comprising:
loading the substrate into a processing chamber; and
introducing a first gaseous organic metal compound source material comprising a first metal, a second gaseous organic metal compound source material comprising a second metal, and an oxidizer into the processing chamber;
wherein a compound having an organic ligand which is decomposed with an oxidizer to produce CO is employed as the first organic metal compound source material; a metallic alkoxide is employed as the second organic metal compound source material; gaseous O₃ or O₂ is employed as the oxidizer; and the second organic metal compound source material is introduced immediately before the introduction of the oxidizer.

12. A non transitory computer-readable storage medium for storing instructions executable by an information processing apparatus which includes a processor, which when executed, controls a film forming apparatus to perform a method for forming an AxByOz oxide film on a substrate, by loading the substrate into a processing chamber and introducing a first gaseous organic metal compound source material comprising a first metal, a second gaseous organic metal compound source material comprising a second metal, and an oxidizer into the processing chamber, the method comprising:
(A) forming a first film by introducing, as the first organic metal compound source material, a compound having an organic ligand which is decomposed with the oxidizer to produce CO into the processing chamber, then introducing the oxidizer into the processing chamber, and then purging the processing chamber; and
(B) forming a second film by introducing the second organic metal compound source material into the processing chamber, then introducing the oxidizer into the processing chamber, and then purging the processing chamber,
wherein each of the forming a first (A) and the second (B) film is continuously performed multiple times, and the forming a first film (A) is repeated less than six times.
